(19) United States
(12) Patent Application Publication
(10) Pub. No.: US 2005/0106895 A1
(43) Pub. Date: May 19, 2005

(54) Supercritical water application for oxide formation

(75) Inventors: Yu-Liang Lin, Hsin Chu (TW); Ping Chuang, Chang-Gung Tsuen (TW); Mei-Sheng Zhou, Singapore (SG)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/715,326

(22) Filed: Nov. 17, 2003

(51) Int. Cl. G06F 17/00; H01L 21/31; H01L 21/469

(52) U.S. Cl. 438/778; 438/782; 700/90

(57) ABSTRACT

The present disclosure provides for a method and system for fabricating an insulating layer on a substrate. The method and system provide a fluid to a substrate, wherein the fluid is provided in an aerosol form. The method and system also provides for generating a supercritical process environment proximate to the substrate. The method and system further provides a proximate supercritical process environment having a supercritical process temperature and a supercritical process pressure for altering the fluid, and placing the substrate in contact with the altered fluid, wherein the insulating layer is formed on the substrate by a reaction between the substrate and the fluid.

### BACKGROUND

The present disclosure relates generally to the field of integrated circuit fabrication and, more particularly, to fabricating an insulating layer on a semiconductor substrate for submicron integrated circuit technologies.

An integrated circuit (IC) is formed by creating one or more devices (e.g., circuit components) on a substrate using a fabrication process. The IC's active device density (i.e., the number of devices per IC area), as well as the IC's functional density (i.e., the number of interconnected devices per IC area), are limited by the fabrication process. An IC fabrication process generally has a number of limitations that affect the formation of a device. One of these limitations is a minimum feature size, which may be viewed as the smallest component (or line) that may be created using the process. Another limitation relates to the formation of insulating layers that serve to isolate the various conductive layers and devices that form an IC.

Insulating layers are widely used in IC manufacturing to provide isolation between conducting and/or semiconducting regions. As the feature sizes of IC components have become smaller and the aspect ratios of features have become higher, the formation of insulating layers has become more difficult. One difficulty is providing a uniform insulating layer without exceeding the thermal budget (i.e., the maximum amount of thermal energy received during processing before degradation occurs) of the semiconductor substrate. Small architectures generally need to be fabricated using relatively low thermal budgets to prevent the diffusion of dopants from previously doped regions. However, conventional methods of insulator fabrication may require processing temperatures and durations that exceed the thermal budget of today's smaller devices.

Another difficulty with the formation of insulating layers involves providing uniform coverage for small formations and deep trenches. For example, forming an insulating layer in a deep trench using conventional methods may result in uneven layer depths or incomplete distribution, both of which may adversely impact IC performance and stability.

Therefore, a system and method are needed for improving the formation of insulating layers at relatively low temperatures.

### SUMMARY

The present disclosure provides for a method and for fabricating an insulating layer on a substrate. The method provides a fluid to a substrate, wherein the fluid is provided in an aerosol form. The method also provides for generating a supercritical process environment proximate to the substrate. The method further provides a proximate supercritical process environment having a supercritical process temperature and a supercritical process pressure for altering the fluid, and placing the substrate in contact with the altered fluid, wherein the insulating layer is formed on the substrate by a reaction between the substrate and the fluid.

The present disclosure also introduces a system for fabricating an insulating layer on a substrate. The system includes a proximate supercritical process environment including a substrate in a processing chamber. The system also provides for a proximate supercritical process environment having a supercritical process temperature and a supercritical process pressure, and control device for controlling the proximate supercritical process environment at a supercritical level. The system also includes a fluid distribution device for providing a non-supercritical fluid to the proximate supercritical process environment in an aerosol form. The system further includes a heating device for heating the substrate to a supercritical temperature, wherein the fluid becomes a supercritical fluid due to the pressure and the temperature proximate the substrate, and wherein the insulator layer is formed by contact between the substrate and the supercritical fluid.

The foregoing has outlined preferred and alternative features of several embodiments so that those skilled in the art may better understand the detailed description that follows. Additional features will be described below that further form the subject of the claims herein. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a flow chart view of one embodiment of a method for forming an insulating layer on a semiconductor substrate constructed according to aspects of the present disclosure.

FIG. 2 illustrates a schematic view of one embodiment of a phase diagram constructed according to aspects of the present disclosure.

FIGS. 3-7b illustrates a sectional view of one embodiment of various devices of constructed according to aspects of the present disclosure.

FIG. 8 illustrates a schematic view of another embodiment of a high pressure reaction system constructed according to aspects of the present disclosure.

### DETAILED DESCRIPTION

The present disclosure relates generally to the field of integrated circuit fabrication and, more particularly, to fabricating an insulating layer on a semiconductor substrate for submicron integrated circuit technologies. It is understood, however, that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

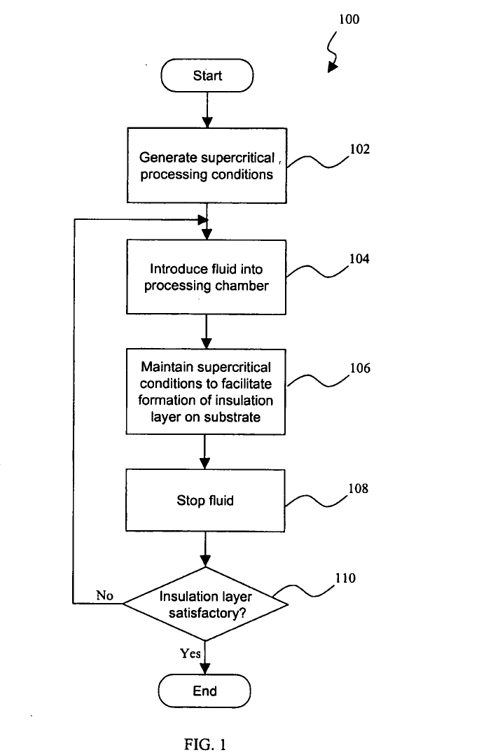

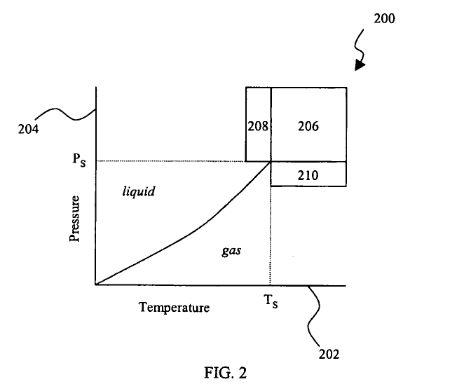

Referring to FIG. 1, illustrates a flow chart view of one embodiment of a method 100 for forming an insulating layer on a semiconductor substrate constructed according to aspects of the present disclosure. In the present example, the semiconductor substrate is positioned on a pedestal within a processing chamber. As will be described later in greater detail, the method 100 uses a supercritical fluid (FIG. 2), to form the insulating layer.

Referring also to FIG. 2, a graph 200 illustrates a relationship between temperature (represented by an x-axis 202) and pressure (represented by a y-axis 204). When a fluid, such as water, reaches a temperature T_{S} and a pressure P_{S}, the fluid enters a supercritical state 206. In this supercritical state 206, liquid and gaseous fluid densities may become equal, and the fluid may possess both liquid and gaseous properties. For example, the supercritical state for water generally occurs at a temperature of about 374° C. and a pressure of about 221 atmospheres. Sub-critical states 208 and 210 represent temperature/pressure relationships where either P_{S} has been reached but the temperature is still below T_{S} (208), or where T_{S} has been reached but the pressure is still below P_{S} (210).

Referring again to FIG. 1, the method 100 begins in step 102 with the generation of supercritical processing conditions (e.g., temperature and pressure). As the present embodiment uses water as the fluid, a temperature of about 374° C. and a pressure of about 221 atmospheres may be generated in the processing chamber to permit the formation of a supercritical water state.

It is noted that the supercritical conditions may be generated in a number of ways. For example, although the pressure conditions within the processing chamber may be held within the supercritical range during processing, the temperature of the processing chamber may remain in a sub-critical range as long as the temperature in the immediate vicinity of the substrate may be within the supercritical range. This allows more processing flexibility as a uniform temperature need not be maintained within the processing chamber. For example, the substrate may be heated to supercritical temperatures using a heated pedestal positioned within the processing chamber. The pedestal may be heated by a resistive coil that may be embedded within or positioned in the vicinity of the pedestal. In one embodiment, the substrate may be heated to a supercritical temperature using a rapid thermal process in which the semiconductor substrate is heated by an infra-red radiation source. The infra-red radiation source may be configured to allow the wavelength of the infra-red radiation source to closely match the infra-red absorption characteristics of silicon and/or other materials.

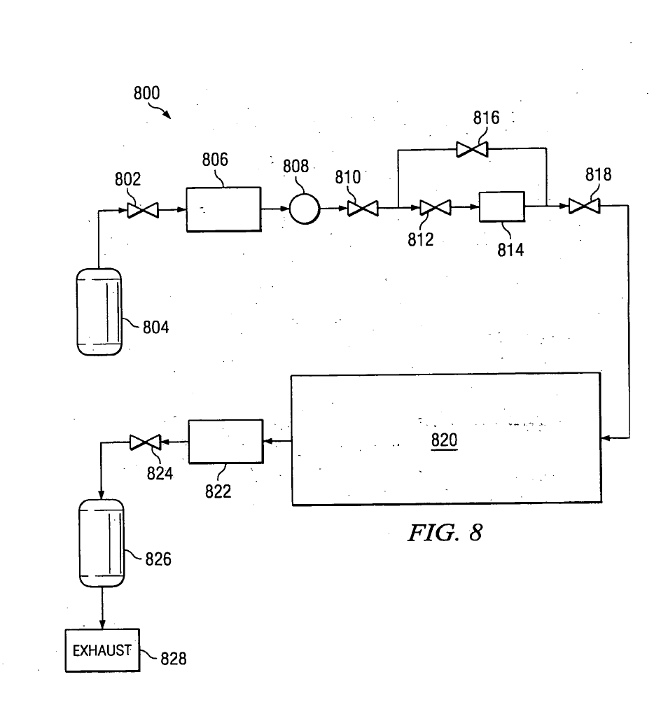

In step 104, fluid is introduced into the processing chamber. For example, the water may be metered and vaporized processing conditions using a liquid mass flow controller coupled with a vaporization module that utilizes an inert or oxygen containing gas to effectively generate the fluid vapor (as shown in FIG. 8). Another exemplary method of introducing fluid into the processing chamber utilizes an aerosol of fluid. The aerosol may be generated by a nebulizer or an ultra-sonic dispersal apparatus below the supercritical processing conditions. Once introduced into the processing chamber, the aerosol of fluid may enter a supercritical state proximate the substrate due to the pressure within the chamber and the temperature within the chamber or at the surface of the substrate.

In step 106, the supercritical conditions are maintained as the semiconductor substrate is exposed to the fluid, causing an insulating layer to form on the substrate. The fluid may be supplied to the substrate continuously until the insulating layer reaches a desired thickness.

In step 108, the flow of fluid into the processing chamber is stopped and, in step 110, a determination is made as to whether the insulating layer is satisfactory (e.g., desired thickness, evenly distributed, etc.). If it is determined in step 110 that the insulation layer is satisfactory, the method 100 ends. However, if it is determined in step 110 that the insulation layer is not satisfactory, the method 100 returns to step 104, where water is again introduced into the processing chamber.

It is understood that step 110 may be used to supply the fluid to the substrate in cycles. For example, the water may be supplied to the substrate for a period ti and then the supply would be stopped for another period, t₂. This process (steps 104-110) may be repeated until the insulating layer reaches the desired thickness. Using this cycling method of applying fluid may allow improved control over the thickness of the insulating layer because the likelihood of overshooting the desired thickness is minimized. Such an application cycle may also provide a denser insulating layer.

One example of an insulating layer that may be formed by the method 100 using supercritical fluid, a silicon substrate, and a wet oxidation process is silicon dioxide (SiO₂). SiO₂ may be thermally grown using a wet oxidation reaction: Si+2H₂O→SiO₂+2H₂. However, traditional methods of wet oxidation use a relatively high processing temperature (e.g., 1150° C.), a relatively low processing pressure (e.g., 1 atmosphere), and have a relatively slow grow rate, such as a range between about 1 and about 2 Angstroms/minute. The high temperatures required and the slow growth rate may adversely affect the use of traditional wet oxidation processes for devices that have low thermal budgets. Additional drawbacks to traditional wet oxidation processes may include high energy costs and non-uniform temperatures inside the processing chamber.

As illustrated by the method 100, one way to improve the traditional wet oxidation process is to use supercritical fluid in the wet oxidation reaction. The use of supercritical fluid may improve the formation of insulating layers in a number of ways. First, supercritical fluid oxidation may be performed at relatively low temperatures compared to traditional wet oxidation processes. For example, supercritical fluid suitable for oxidation may be generated at a pressure of about 22.1 MPa and a temperature of about 374° C. This represents a significant temperature reduction from the 1150° C. temperature commonly used in traditional wet oxidation.

The use of supercritical fluid also enhances the rate of oxidation. For example, even at the lowered processing temperatures associated with supercritical processing, the rate of oxidation may exceed traditional wet oxidation methods. This increased rate of oxidation may occur because, as water density is lowered, diffusivity and ion mobility become higher. As one example, processing conditions of about 374° C. and about 221 atmospheres may cause silicon exposed to supercritical-water to oxidize at a rate of more than about 5 Angstroms per minute.

Supercritical water may also provide improved insulating layer formation, especially for high aspect ratio features. Supercritical water may be characterized by low viscosity and low surface tension, properties which permit the supercritical water to penetrate into narrow trenches and provide uniform coverage. Consequently, uniform oxide formation may occur even in extremely narrow and deep features.

Supercritical fluid may also provide in situ cleaning of a semiconductor substrate because its low polarity and low surface tension may aid in removing organic contaminates from the substrate surface. The low polarity, due primarily to the loss of hydrogen bonding under the supercritical processing conditions, may allow nonpolar organics to become soluble in the supercritical water or combine with the O₂ in the processing chamber, allowing the nonpolar organics to be driven off of the substrate by effluent water, CO₂, or another suitable fluid.

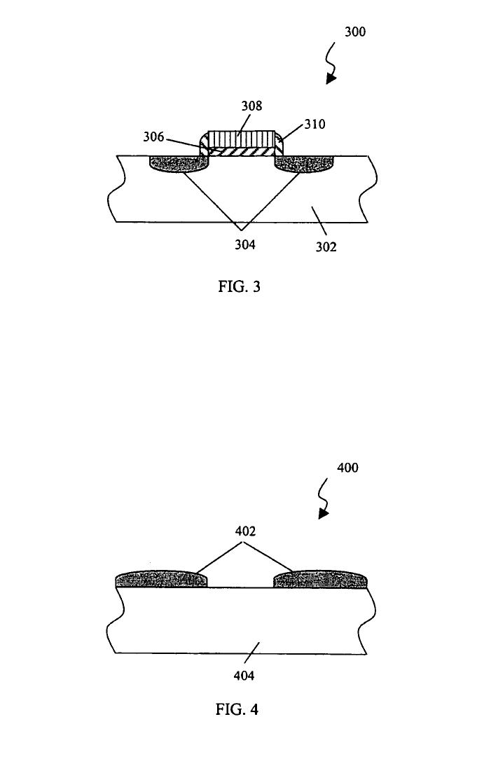

Referring now to FIG. 3, a field effect transistor (FET) 300 is one example of an IC device having an insulating layer that may be fabricated using the method 100 of FIG. 1. The FET includes a substrate 302 which may be, for example, silicon, diamon, silicon on insulator (SOI), or silicon-geranium (SiGe). The substrate 302 may be doped either p-type or n-type. N-type or p-type (depending on the dopant used in the substrate) doped wells 304 may be formed in the substrate 302 using a variety of dopants. For example, phosphorus may be used as an n-type dopant, while boron may be used as a p-type dopant. The dopants may be incorporated by methods such as ion implantation, gaseous diffusion, CVD, PECVD, ALD, or other suitable methods.

In one embodiment, the field effect transistor (FET) 300 may comprise a diamond substrate 302 including a plurality of boron doped regions and a plurality of deuterium-boron complex regions. The boron doped regions comprising a plurality of p-type regions, and the deuterium-boron complex regions comprising a plurality of n-type regions. The boron doped regions and the deuterium-boron complex regions may be utilized to form a plurality of source and drain regions for a plurality of microelectronics devices upon the substrate 302.

The boron doped regions (boron doped diamond) may be formed using high density plasma source with a carbon to deuterium ratio ranging between about 0.1 percent and about 5 percent in a vacuum process ambient. Boron doping may be provided by the mixing of a boron containing gas with the carbon/hydrogen gas. The boron containing gas may include B₂H₆, B₂D₆, or other boron containing gases. The concentration of boron doping may depend upon the amount of boron containing gas that may be leaked into the process. The process ambient pressure may range between 0.1 mTorr and about 500 Torr. The substrate 302 may be held at a temperature between 150° C. and about 1100° C. The high density plasma may be produced by a microwave electron cyclotron resonance (ECR) plasma, a helicon plasma, a inductively coupled plasma, or other high density plasma sources. For example, the ECR plasma may utilize microwave powers ranging between about 800 Watts and about 2500 Watts.

The n-type deuterium-boron complex regions of the substrate 302 may be formed by a subsequent treatment employing a deuterium plasma of the boron doped region. Selected areas of the field effect transistor (FET) 300 may be covered by a mask (not shown) and uncovered boron doped regions may be treated with a deuterium containing plasma. The deuterium ions provide termination of dangling bonds, thereby transmuting the p-type region into a n-type region. Alternatively, deuterium may be replaced with tritium, hydrogen, or other hydrogen containing gases. The concentration of the n-type region (deuterium-boron complex region) may be controlled by a direct current (DC) or a radio frequency (RF) bias of the substrate 302.

An insulating layer 306 may then be formed between the doped wells 304 using the method 100 of FIG. 1. The insulating layer 306 may have a thickness ranging between about 1 and about 100 Angstroms and, after its formation, may be patterned and etched to form the shape and thickness required for a FET gate insulator. A conductive layer 308 may then formed over the insulating layer 306 to form a gate. The conductive layer 308 may be formed from a conductive material such as doped polysilicon or a metal silicide using a thermal oxidation furnace at temperatures ranging between about 700° and about 900° C. Alternatively, a rapid thermal anneal (RTA) process may be used in which the substrate is exposed to temperatures ranging between about 450° and about 1000° C. for a range between about 3 and about 60 seconds.

A spacer 310 may be formed around the insulating layer 306 and the conductive layer 308 using the method 100 of FIG. 1. The method 100 may be advantageous for spacer formation because supercritical water oxidation may be performed without exposing the FET 300 to the higher temperatures associated with the conventional oxide deposition processes such as CVD, ALD, or PECVD of tetraethylorthosilicate (TEOS). Using supercritical water oxidation in the formation of spacers also provides an in situ cleansing of organic contaminates from the surface of the conductive layer 308, the insulating layer 306, the doped wells 304, and the substrate 302, while the spacer 310 is formed.

Referring now to FIG. 4, another example of a structure that may be formed using the method 100 of FIG. 1 is a local oxidation of silicon (LOCOS) structure 400, such as may be used to electrically isolate active devices in an integrated circuit. A LOCOS structure 400 may have a plurality of insulating isolation areas 402 formed on a semiconductor substrate 404. The isolation areas 402 may be formed using the process 100 of FIG. 1.

Referring now to FIG. 5, still another example of a structure that may be formed using the method 100 of FIG. 1 is a damascene structure 500. Damascene structures are used in IC fabrication to create interconnections between IC elements. The damascene structure 500 may include a plurality of interconnections 502, such as conducting lines, contacts, or vias. The interconnections 502 may be connected to a plurality of IC front end devices 504, such as FETs, that are located on a semiconductor substrate 506. The interconnections 502 are formed in layers of dielectric material 508 which insulate the metal of the interconnections 502 and isolate the interconnections from each other. The method 100 of FIG. 1 may be used to form the dielectric material 506. The interconnections 502 may include a bulk fill conducting material such as copper and a barrier layer (not shown), such as Ta, TaN, Ti, TiN, TiW, or WN. The barrier layer may minimize or prevent copper diffusion that may otherwise occur when the interconnections are heated during the generation of the supercritical fluid.

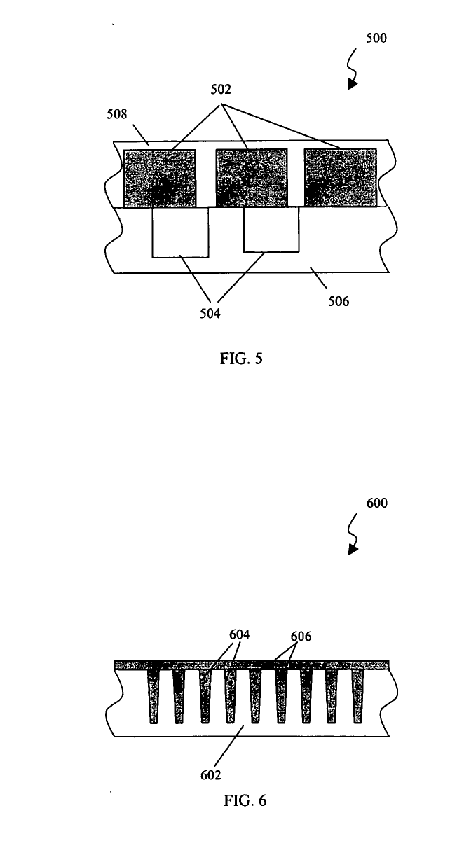

Referring now to FIG. 6, still another structure that may be formed using the method 100 of FIG. 1 is a semiconductor structure 600. The structure 600 includes a substrate 602 with a plurality of high aspect ratio trenches 604 covered by an insulating layer 606, which may be formed using the method 100 of FIG. 1. The trenches 604 may be used, for example, in the formation of a floating gate or in the creation of an electrode for an erasable programmable read only memory (EPROM) or electrically erasable PROM device. Electrical isolation of semiconductor devices may also utilize the trenches 604. The supercritical fluid used in the method 100 may be used for filling the trenches 604 because the low viscosity and low surface tension properties of supercritical fluid permit uniform coverage and, consequently, uniform oxide formation even in extremely narrow and deep features such as the trenches 604.

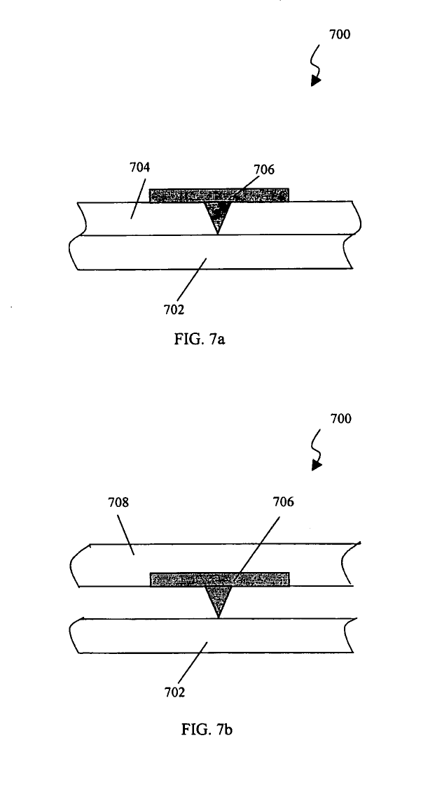

Referring now to FIG. 7a, the method 100 of FIG. 1 may also be used to form an insulating layer for an electromechanical micro-machine device 700, which may be a digital mirror device, a mechanical gear, a lever, a core material for an accelerometer, a clinometer, or a gyroscope. The micro-machine device 700 may be created on a semiconductor substrate 702 using alternate layers of sacrificial materials and structural materials as follows.

A first sacrificial layer 704 may be formed using the method 100 of FIG. 1. The first sacrificial layer 704 may be deposited as an interim means of supporting the structural layer 706 that will later become free standing. After the structural layer 706 is deposited, the first sacrificial layer 704 may be etched away leaving the structural layer 706 suspended over the substrate 702. The supercritical fluid used in the process 100 may create the first sacrificial layer 704 effectively because of the supercritical fluid's ability to penetrate intricate crevasses to permit oxide formation.

Referring also to FIG. 7b, the method 100 may also be used to create a second sacrificial layer 708, which may provide protection and suspension for the structural layer 706 after the first sacrificial layer 704 has been removed.

Referring now to FIG. 8, a schematic layout 800 represents one example of a high pressure reaction system which may be used for the creation and delivery of supercritical fluid to a substrate surface. A process cycle, such as may be used to implement the method 100 of FIG. 1, may begin at a valve 802, which may regulate the flow of fluid from a make-up tank 804 to a working tank 806. A fluid pump 808 may direct the flow of fluid from the working tank 806 through a valve 810 towards a preheater 814. A valve 812 may allow the fluid to enter the preheater 814 to reach a supercritical temperature or, alternatively, the valve 812 may be closed and a valve 816 may be opened to divert the flow of fluid around the preheater 814.

A valve 818 may be manipulated to permit the fluid to enter a process chamber 820 where a substrate (not shown) may be provided. The process chamber 820 may contain valves (not shown) that may be closed to temporarily stop the flow of the supercritical fluid into the process chamber 820. During this time, the pressure in the process chamber 820 may be released to allow a processed substrate to be replaced with an un-processed substrate. The pressure in the process chamber 820 may range between about 50 and about 800 atmospheres during processing. A chamber pressure regulator 824 may be attached to the process chamber 820 which, together with a pressure gauge 822, allows the pressure in the process chamber 820 to be controlled.

Inert gases such as Ar, N₂, H₂, and O₂ may be supplied to the process chamber 820 for mixing with the supercritical water. The pressure gauge 822 and pressure regulator 824 may be used to control the flow of water into a lower pressure expansion vessel 826, which may be held at a lower temperature and pressure than the process chamber 820. Generally, the lower pressure expansion vessel 826 may have a temperature ranging between about 0° C. and about 32° C. and a pressure ranging between about 15 and about 2000 psi. After leaving the expansion vessel 826, the water may enter an exhaust system 828, where the pressure may be slightly below about 1 atmosphere and the temperature may be lower than that of the expansion vessel 826. Alternatively, the exhaust system 828 may be a reclamation system for the water. The water may be recycled, purified, and redirected to the working tank using the reclamation system 828.

The present disclosure has been described relative to a preferred embodiment. Improvements or modifications that become apparent to persons of ordinary skill in the art only after reading this disclosure are deemed within the spirit and scope of the application. For example, it is understood that the method 100 of FIG. 1 may be used in a variety of applications, and FIGS. 3-7b represent only a few of the applications. It is understood that several modifications, changes and substitutions are intended in the foregoing disclosure and in some instances some features of the disclosure will be employed without a corresponding use of other features. Accordingly, it is appropriate that the appended claims be construed broadly and in a manner consistent with the scope of the disclosure.

1. A method for fabricating an insulating layer on a substrate, comprising:
providing a fluid to a substrate, wherein the fluid is provided in an aerosol form;
generating a supercritical process environment proximate to the substrate, the proximate supercritical process environment having a supercritical process temperature and a supercritical process pressure for altering the fluid; and
placing the substrate in contact with the altered fluid, wherein the insulating layer is formed on the substrate by a reaction between the substrate and the fluid.

2. The method of claim 1 further comprising:
converting the fluid from a liquid to the aerosol form; and
distributing the fluid in the aerosol form using an ultrasonic applicator.

3. The method of claim 1 further comprising:
converting the fluid from a liquid to the aerosol form; and
distributing the fluid in the aerosol form using a nebulizer.

4. The method of claim 1 wherein the fluid comprises water.

5. The method of claim 1 wherein the fluid is heated prior to being provided to the processing chamber.

6. The method of claim 1 wherein the substrate comprises a diamond, the substrate including a n-type region and a p-type region.

7. The method of claim 6 wherein the p-type region comprises a boron doped region.

8. The method of claim 6 wherein the n-type region comprises a deuterium-boron complex region, the n-type layer formed by a plasma treatment of the boron doped region.

9. The method of claim 1 further comprising heating the substrate to the supercritical process temperature, wherein the water is heated to the supercritical process temperature by the heated substrate.

10. The method of claim 9 further comprising heating a pedestal holding the substrate with a resistive coil.

11. The method of claim 9 wherein heating the substrate includes irradiating the substrate with infra-red radiation.

12. The method of claim 1 further comprising removing the substrate from contact with the heated fluid, wherein the substrate is repeatedly placed in contact with the heated fluid and removed from contact with the heated fluid until a desired thickness of the insulating layer is formed.

13. The method of claim 1 further including forming a conductive layer over the insulating layer.

14. The method of claim 1 further comprising removing at least a portion of the insulating layer to form a spacer around a gate of a transistor.

15. The method of claim 1 wherein the insulating layer isolates a plurality of interconnections in a damascene structure.

16. The method of claim 1 wherein the supercritical process temperature is approximately 374° C. and wherein the supercritical process pressure is approximately 221 atmospheres.

17. The method of claim 1 further comprising:
determining whether the insulating layer is of a predetermined thickness; and
maintaining the contact between the substrate and the heated fluid if the insulating layer is not of the predetermined thickness.

18. A system for fabricating an insulating layer on a substrate, comprising:
a supercritical process environment including a substrate in a processing chamber, the processing chamber having a process temperature and a process pressure;
a control device for controlling the processing chamber at a supercritical level;
a fluid distribution device for providing a non-supercritical fluid to the processing chamber in an aerosol form; and
a heating device for heating the substrate to a supercritical temperature, wherein the fluid becomes a supercritical fluid due to the process pressure and the process temperature of the processing chamber, and wherein the insulator layer is formed by contact between the substrate and the supercritical fluid.

19. The system of claim 18 wherein the control device controls the supercritical level of the processing chamber at a process pressure of about 221 atmospheres and at a process temperature of about 374° C.

20. The system of claim 18 wherein the fluid distribution device is an ultrasonic applicator.

21. The system of claim 18 wherein the fluid distribution device is a nebulizer.

22. The system of claim 18 wherein the heater is positioned proximate to the substrate for heating the substrate to the supercritical temperature.

23. The system of claim 18 wherein a temperature throughout the processing chamber is not uniform.

24. A system for fabricating an insulating layer on a substrate, comprising:
a processing chamber for housing a semiconductor substrate;
a control device for controlling the chamber at a supercritical level;
a fluid distribution device for providing a non-supercritical fluid to the chamber; and
a device for converting the fluid to a supercritical state using enhanced pressure and/or temperature proximate the substrate, and wherein the insulator layer is formed by contact between the substrate and the supercritical fluid.

25. The system of claim 24 wherein the fluid distribution device is an ultrasonic applicator.

26. The system of claim 24 wherein the fluid distribution device is a nebulizer.

27. The system of claim 24 wherein the semiconductor substrate comprises a diamond, the substrate including a n-type region and a p-type region.

28. The system of claim 27 wherein the p-type region comprises a boron doped region.

29. The system of claim 27 wherein the n-type region comprises a deuterium-boron complex region, the n-type layer formed by a plasma treatment of the boron doped region.

30. The system of claim 24 wherein the fluid distribution device is operable to cycle between providing fluid to the process chamber and providing no fluid to the process chamber until the insulating layer reaches a desired thickness, wherein the cycle is defined by a timer associated with the fluid distribution device.

31. The system of claim 24 wherein the converting device is positioned proximate to the substrate for heating the substrate to the supercritical temperature.

32. The system of claim 31 wherein a temperature throughout the chamber is non-uniform.
